(19) United States
(12) Patent Application Publication
(10) Pub. No.: US 2026/0310092 A1
(43) Pub. Date: Oct. 8, 2026

(54) CURVILINEAR LITHOGRAPHY MASKS AND GEOMETRY-BASED MASK CHECK RULES FOR CURVILINEAR LITHOGRAPHY MASKS

(71) Applicant: Taiwan Semiconductor Manufacturing Company, Ltd., Hsinchu (TW)

(72) Inventor: Wen LO, Hsinchu (TW)

(73) Assignee: Taiwan Semiconductor Manufacturing Company, Ltd., Hsinchu (TW)

(21) Appl. No.: 19/171,701

(22) Filed: Apr. 7, 2025

(51) Int. Cl. G03F 7/00; G03F 1/36; G03F 7/18

(52) U.S. Cl. CPC G03F 7/70441; G03F 1/36

(57) ABSTRACT

According to various embodiments, a method of manufacturing a lithography mask includes receiving an initial mask design having a first curved feature, determining an edge placement error, generating a corrected mask design based on the edge placement error, and fabricating the lithography mask based on the corrected mask design. Determining the edge placement error includes approximating the first curved feature by a cosine function, determining an arc length of the cosine function between two endpoints that are symmetrically located on the first curved feature, determining a chord length between the two endpoints, and determining a value of the edge placement error to be a linear function of a first ratio of the arc length to the chord length. In other embodiments, the edge placement error is a value that is proportional to a second ratio of a squared standard deviation divided by a squared characteristic wavelength of the cosine function.

### BACKGROUND

Integrated circuit (IC) design becomes more challenging as IC technologies continually progress towards smaller feature sizes, such as 32 nm, 28 nm, 20 nm, and below. For example, when fabricating IC devices, IC device performance is seriously influenced by lithography printability capability, which indicates how well a final wafer pattern formed on a wafer corresponds with a target pattern defined by an IC design layout. Various methods that focus on optimizing a mask used for projecting an image that corresponds with the target pattern on the wafer have been introduced for enhancing lithography printability, such as optical proximity correction (OPC), mask proximity correction (MPC), inverse lithography technology (ILT), and source mask optimization (SMO). Although such methods have provided improvements to mask technology, many challenges remain.

### BRIEF DESCRIPTION OF THE DRAWINGS

The present disclosure is best understood from the following detailed description when read with the accompanying figures. It is emphasized that, per the standard practice in the industry, various features are not drawn to scale and are used for illustration purposes only. The dimensions of the various features may be arbitrarily increased or reduced for clarity of discussion.

FIG. 1 is a block diagram of an integrated circuit (IC) manufacturing system, along with an IC manufacturing flow associated with the IC manufacturing system, according to various embodiments.

FIG. 2 is a block diagram of an optical lithography system, which can be implemented by the IC manufacturing system of FIG. 1, according to various embodiments.

FIG. 3 is a schematic illustrating an OPC-based computational lithography process, which can be implemented by the IC manufacturing system of FIG. 1, according to various aspects of the present disclosure.

FIG. 4A illustrates a portion of an initial mask design including curved features according to various embodiments.

FIG. 4B illustrates a projected pattern based on the initial mask design that includes edge placement errors according to various embodiments.

FIG. 4C illustrates a corrected mask design according to various embodiments.

FIG. 5A is a plot illustrating diffraction effects for a single Fourier component having an 80 nm wavelength according to various embodiments.

FIG. 5B is a plot illustrating diffraction effects for a single Fourier component having a 120 nm wavelength according to various embodiments.

FIG. 5C is a plot illustrating diffraction effects for a single Fourier component having a 160 nm wavelength according to various embodiments.

FIG. 5D is a plot illustrating diffraction effects for a single Fourier component having a 200 nm wavelength according to various embodiments.

FIG. 5E is an enlarged portion of FIG. 5A showing edge placement errors caused by diffraction effects according to various embodiments.

FIG. 6 is a two-dimensional plot of a first curved portion of an initial mask design and a second curved portion of a projected pattern according to various embodiments.

FIG. 7 is a plot of absolute edge placement error vs. an arc/chord ratio that verifies a linear relationship according to various embodiments.

FIG. 8 is a flowchart illustrating operations of a method of manufacturing a lithography mask according to an embodiment.

FIG. 9A is a flowchart illustrating operations of a method of determining edge placement error in the method of FIG. 8, according to an embodiment.

FIG. 9B is a flowchart illustrating operations of a method of determining edge placement error in the method of FIG. 8, according to an embodiment.

FIG. 10A illustrates an apparatus for performing the methods of FIGS. 8, 9A, and 9B, according to various embodiments.

FIG. 10B is a schematic layout of components of the apparatus of FIG. 10A, according to various embodiments.

### DETAILED DESCRIPTION

It is to be understood that the following disclosure provides many different embodiments, or examples, for implementing different features of the invention. Specific embodiments or examples of components and arrangements are described below to simplify the present disclosure. These are, of course, merely examples and are not intended to be limiting. For example, dimensions of elements are not limited to the disclosed range or values but may depend upon process conditions and/or desired properties of the device. Moreover, the formation of a first feature over or on a second feature in the description that follows include embodiments in which the first and second features are formed in direct contact, and may also include embodiments in which additional features may be formed by interposing the first and second features, such that the first and second features may not be in direct contact. Various features may be arbitrarily drawn in different scales for simplicity and clarity.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In addition, the term “being made of” may mean either “comprising” or “consisting of.” In the present disclosure, the phrase “one of A, B and C” means “A, B and/or C” (A, B, C, A and B, A and C, B and C, or A, B and C), and does not mean one element from A, one element from B and one element from C, unless otherwise described.

Disclosed embodiments are advantageous by providing mask rule checkers that allow fast and efficient estimates of edge placement errors in mask design, avoiding the need for costly and time-consuming numerical simulations. Disclosed embodiments are based on fundamental principles of physical optics combined with geometric considerations of curved mask features and have been validated by both experiments and simulations. According to various embodiments, determining the edge placement error includes approximating a curved feature by a cosine function, determining an arc length of the cosine function between two endpoints that are symmetrically located on the curved feature, determining a chord length between the two endpoints, and determining a value of the edge placement error to be a linear function of a first ratio of the arc length to the chord length. In other embodiments, the edge placement error is a value that is proportional to a second ratio of a squared standard deviation (characterizing diffraction effects) divided by a squared characteristic wavelength of the cosine function.

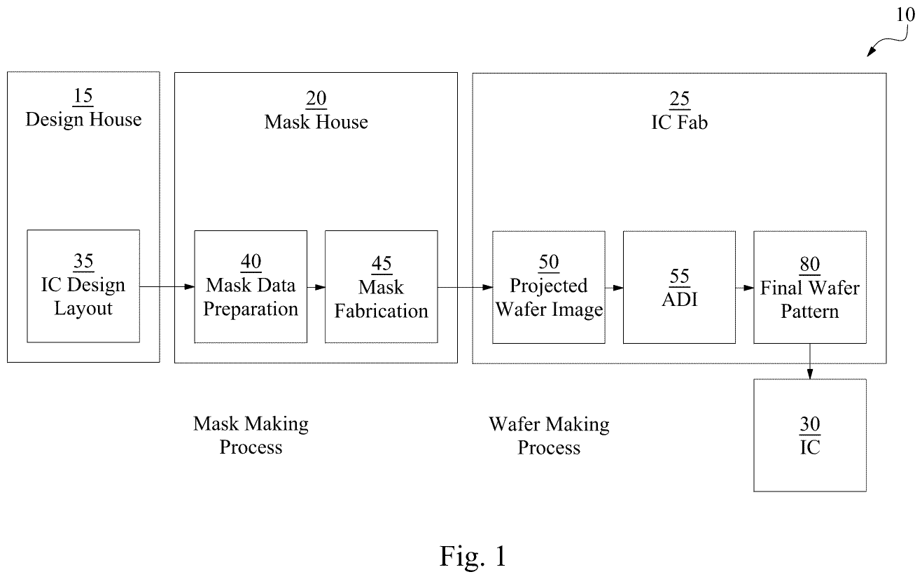

FIG. 1 is a block diagram of an integrated circuit (IC) manufacturing system 10, along with an IC manufacturing flow associated with the IC manufacturing system 10, according to various embodiments. The IC manufacturing system 10 includes a plurality of entities, such as a design house (or design team) 15, a mask house 20, and an IC manufacturer 25 (for example, an IC fab), that interact with one another in design, development, and manufacturing cycles and/or services related to manufacturing an IC device 30. The plurality of entities is connected by a communication network, which may be a single network or a variety of different networks, such as an intranet and/or the Internet, and includes wired and/or wireless communication channels. Each entity may interact with other entities and may provide services to and/or receive services from the other entities. One or more of the design house 15, the mask house 20, and the IC manufacturer 25 may be owned by a single large company, and may even coexist in a common facility and use common resources.

The design house 15 generates an IC design layout 35 (also referred to as an IC design pattern). The IC design layout 35 includes various circuit patterns (represented by geometrical shapes) designed for an IC product based on specifications of an IC product to be manufactured. The circuit patterns correspond to geometrical patterns formed in various material layers (such as metal layers, dielectric layers, and/or semiconductor layers) that combine to form IC features (components) of the IC product, such as the IC device 30. For example, a portion of the IC design layout 35 includes various IC features to be formed in a substrate (for example, a silicon substrate) and/or in various material layers disposed on the substrate. The various IC features include an active region, a gate feature (for example, a gate dielectric and/or a gate electrode), a source/drain feature, an interconnection feature, a bonding pad feature, other IC features, or combinations thereof. In some implementations, assist features are inserted into the IC design layout 35 to provide imaging effects, process enhancements, and/or identification information.

A geometry proximity correction (GPC) process, similar to an OPC process used for optimizing mask patterns (mask layouts), generates the assist features based on environmental impacts associated with IC fabrication, including etching loading effects, patterning loading effects, and/or chemical mechanical polishing (CMP) process effects. The design house 15 implements a design procedure to form the IC design layout 35. The design procedure includes logic design, physical design, placement and routing, or combinations thereof. The IC design layout 35 is presented in one or more data files that include information of the circuit patterns (geometrical patterns).

The mask house 20 uses the IC design layout 35 to manufacture one or more masks, which are used for fabricating various layers of the IC device 30 according to the IC design layout 35. A mask (also referred to as a photomask or reticle) refers to a patterned substrate used in a lithography process to pattern a wafer, such as a semiconductor wafer. The mask house 20 performs mask data preparation 40, where the IC design layout 35 is translated into a form that can be written by a mask writer to generate a mask. For example, the IC design layout 35 is translated into machine readable instructions for a mask writer. Mask data preparation 40 generates a mask pattern (mask layout) that corresponds with a target pattern defined by the design layout 35. The mask pattern is generated by fracturing the target pattern of the IC design layout 35 into a plurality of mask features (mask regions) suitable for a mask making lithography process.

The fracturing process is implemented according to various factors, such as IC feature geometry, pattern density differences, and/or critical dimension (CD) differences, and the mask features are defined based on methods implemented by the mask writer for printing mask patterns. In some implementations, a mask pattern is generated by fracturing the IC design layout 35 into polygons (such as rectangles or trapezoids), where exposure information is generated for each polygon. Exposure information can define an exposure dose, an exposure time, and/or an exposure shape, for each polygon. As described in detail below, mask data preparation 40 can implement various processes for optimizing the mask pattern, such that a final pattern formed on a wafer (often referred to as a final wafer pattern) by a lithography process using a mask fabricated from the mask pattern exhibits enhanced resolution and precision.

The mask house 20 also performs mask fabrication 45, where a mask is fabricated according to the mask pattern generated by mask data preparation 40. In some implementations, the mask pattern is modified during mask fabrication 45 to comply with a particular mask writer and/or mask manufacturer. During mask fabrication 45, a mask making process is implemented that fabricates a mask based on the mask pattern (mask layout). The mask includes a mask substrate and a patterned mask layer, where the patterned mask layer includes a final (real) mask pattern.

The final mask pattern, such as a mask contour, corresponds with the mask pattern (which corresponds with the target pattern provided by the IC design layout 35). In some implementations, the mask is a binary mask. In such implementations, according to one example, an opaque material layer (such as chromium) is formed over a transparent mask substrate (such as a fused quartz substrate or calcium fluoride (CaF₂) substrate), and the opaque material layer is patterned based on the mask pattern to form a mask having opaque regions and transparent regions. In some implementations, the mask is a phase shift mask (PSM) that can enhance imaging resolution and quality, such as an attenuated PSM or alternating PSM. In such implementations, according to one example, a phase shifting material layer (such as molybdenum silicide (MoSi) or silicon dioxide (SiO₂)) is formed over a transparent mask substrate (such as a fused quartz substrate or calcium fluoride (CaF₂) substrate), and the phase shifting material layer is patterned to form a mask having partially transmitting, phase shifting regions and transmitting regions that form the mask pattern.

In another example embodiment, the phase shifting material layer is a portion of the transparent mask substrate, such that the mask pattern is formed in the transparent mask substrate. In some implementations, the mask is an extreme ultraviolet (EUV) mask. In such implementations, according to one example, a reflective layer is formed over a substrate, an absorption layer is formed over the reflective layer, and the absorption layer (such as a tantalum boron nitride (TaBN)) is patterned to form a mask having reflective regions that form the mask pattern. The substrate includes a low thermal expansion material (LTEM), such as fused quartz, TiO₂ doped SiO₂, or other suitable low thermal expansion materials. The reflective layer can include multiple layers formed on the substrate, where the multiple layers include a plurality of film pairs, such as molybdenum-silicon (Mo/Si) film pairs, molybdenum-beryllium (Mo/Be) film pairs, or other suitable material film pairs configured for reflecting EUV radiation (light). The EUV mask may further include a capping layer (such as ruthenium (Ru)) disposed between the reflective layer and the absorption layer. Alternatively, another reflective layer is formed over the reflective layer and patterned to form an EUV phase shift mask.

Mask fabrication 45 can implement various lithography processes for fabricating the mask. For example, the mask-making process includes a lithography process, which involves forming a patterned energy-sensitive resist layer on a mask material layer and transferring a pattern defined in the patterned resist layer to the mask patterning layer. The mask material layer is an absorption layer, a phase-shifting material layer, an opaque material layer, a portion of a mask substrate, and/or other suitable mask material layer. In some implementations, forming the patterned energy-sensitive resist layer includes forming an energy-sensitive resist layer on the mask material layer (for example, by a spin coating process), performing a charged particle beam exposure process, and performing a developing process. The charged particle beam exposure process directly “writes” a pattern into the energy-sensitive resist layer using a charged particle beam, such as an electron beam or an ion beam. Since the energy-sensitive resist layer is sensitive to charged particle beams, exposed portions of the energy-sensitive resist layer chemically change, and exposed (or non-exposed) portions of the energy-sensitive resist layer are dissolved during the developing process depending on characteristics of the energy-sensitive resist layer and characteristics of a developing solution used in the developing process.

After development, the patterned resist layer includes a resist pattern that corresponds with the mask pattern. The resist pattern is then transferred to the mask material layer by any suitable process, such that a final mask pattern is formed in the mask material layer. For example, the mask making process can include performing an etching process that removes portions of the mask material layer, where the etching process uses the patterned energy-sensitive resist layer as an etch mask during the etching process. After the etching process, the lithography process can include removing the patterned energy-sensitive resist layer from the mask material layer, for example, by a resist stripping process.

The IC manufacturer 25, such as a semiconductor foundry, uses the mask (or masks) fabricated by mask house 20 to fabricate the IC device 30. For example, a process is implemented that uses a mask to fabricate a portion of the IC device 30 on a wafer, such as a semiconductor wafer. In some implementations, IC manufacturer 25 performs wafer-making processes numerous times using various masks to complete fabrication of the IC device 30. Depending on the IC fabrication stage, the wafer can include various material layers and/or IC features (for example, doped features, gate features, and/or interconnect features) when undergoing the wafer-making process. The wafer-making process includes a lithography process, which involves forming a patterned resist layer on a wafer material layer using a mask, such as the mask fabricated by mask house 20, and transferring a pattern defined in the patterned resist layer to the wafer material layer. The wafer material layer is a dielectric layer, a semiconductor layer, a conductive layer, a portion of a substrate, and/or other suitable wafer material layer in some embodiments.

Forming the patterned resist layer can include forming a resist layer on the wafer material layer (for example, by spin coating), performing a pre-exposure baking process, performing an exposure process using the mask (including mask alignment), performing a post-exposure baking process, and performing a developing process. During the exposure process, the resist layer is exposed to radiation energy (such as ultraviolet (UV) light, deep UV (DUV) light, or extreme UV (EUV) light) using an illumination source, where the mask blocks, transmits, and/or reflects radiation to the resist layer depending on a final mask pattern of the mask and/or mask type (for example, binary mask, phase shift mask, or EUV mask), such that an image is projected onto the resist layer that corresponds with the final mask pattern.

This image is referred to herein as a projected wafer image 50. Since the resist layer is sensitive to radiation energy, exposed portions of the resist layer chemically change, and exposed (or non-exposed) portions of the resist layer are dissolved during the developing process depending on characteristics of the resist layer and characteristics of a developing solution used in the developing process. After development, the patterned resist layer includes a resist pattern that corresponds with the final mask pattern. An after-development inspection (ADI) 55 can be performed to capture information associated with the resist pattern, such as critical dimension uniformity (CDU) information, overlay information, and/or defect information.

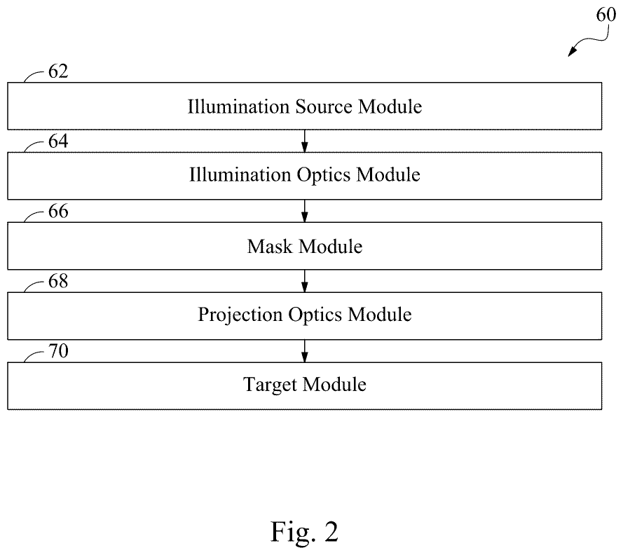

FIG. 2 is a block diagram of an optical lithography system 60 for imaging a pattern of a mask onto a workpiece, which can be implemented by the IC fab 25, according to various embodiments. The workpiece includes a wafer, a mask, or any base material on which processing is conducted to produce layers of material configured to form IC patterns and/or IC features. In some implementations, the workpiece is a wafer having a radiation-sensitive layer (for example, a resist layer) disposed thereover. In FIG. 2, optical lithography system 60 includes an illumination source module 62, an illumination optics module 64, a mask module 66, a projection optics module 68, and a target module 70.

The illumination source module 62 includes a radiation source that generates and emits radiation (light) of a suitable wavelength, such as UV radiation, DUV radiation, EUV radiation, other suitable radiation, or a combination thereof. The illumination optics module 64 collects, guides, and directs the radiation, such that the radiation is projected onto a mask. The mask module 66 includes a mask stage for holding the mask and manipulating a position of the mask. The mask transmits, absorbs, and/or reflects the radiation depending on a final mask pattern of the mask, along with mask technologies used to fabricate the mask, thereby projecting patterned radiation.

The projection optics module 68 collects, guides, and directs the patterned radiation from the mask module 66 to a workpiece in the target module 70, such that an image of the mask (corresponding with the final mask pattern) is projected onto the workpiece. The target module 70 can include a wafer stage for holding the workpiece and manipulating a position of the workpiece. In some implementations, the target module 70 provides control of a position of the workpiece, such that an image of the mask can be scanned onto the workpiece in a repetitive fashion (though other scanning methods are possible). In some implementations, the illumination optics module 64 includes various optical components for collecting, directing, and shaping the radiation onto the mask, and the projection optics module 68 includes various optical components for collecting, directing, and shaping the patterned radiation onto the workpiece. Such optical components include refractive components, reflective components, magnetic components, electromagnetic components, electrostatic components, and/or other types of components for collecting, directing, and shaping the radiation. FIG. 2 is simplified for the sake of clarity to better understand the inventive concepts of the present disclosure. Additional features can be added to the optical lithography system 60, and some of the features described below can be replaced, modified, or eliminated for additional embodiments of the optical lithography system 60.

The wafer making process implemented by the IC manufacturer 25 (see FIG. 1), including transferring the resist pattern defined in the patterned resist layer to the wafer material layer is accomplished in numerous ways, such that a final wafer pattern 80 is formed in the wafer material layer. For example, the wafer making process can include performing an implantation process to form various doped regions/features in the wafer material layer, where the patterned resist layer is used as an implantation mask during the implantation process. In another example, the wafer making process includes performing an etching process that removes portions of the wafer material layer, where the etching process uses the patterned resist layer as an etch mask during the etching process.

After the implantation process or the etching process, the lithography process includes removing the patterned resist layer from the wafer, for example, by a resist stripping process. In yet another example, the wafer making process includes performing a deposition process that fills openings in the patterned resist layer (formed by the removed portions of the resist layer) with a dielectric material, a semiconductor material, or a conductive material. In such implementations, removing the patterned resist layer leaves a wafer material layer that is patterned with a negative image of the patterned resist layer. An after etch inspection (AEI) can be performed to capture information, such as CDU, associated with the final wafer pattern 80 formed in the wafer material layer.

Ideally, the final wafer pattern 80 matches the target pattern defined by the IC design layout 35. However, due to various factors associated with the mask making process and the wafer making process, the final mask pattern formed on the mask often varies from the mask pattern (generated from the target pattern defined by the IC design layout 35), causing the final wafer pattern 80 formed on the wafer to vary from the target pattern. For example, mask writing blur (such as e-beam writing blur) and/or other mask making factors cause variances between the final mask pattern and the mask pattern, which causes variances between the final wafer pattern 80 and the target pattern. Various factors associated with the wafer making process (such as resist blur, mask diffraction, projection imaging resolution, acid diffusion, etching bias, and/or other wafer making factors) further exacerbate the variances between final wafer pattern 80 and the target pattern.

Computational lithography has been introduced for enhancing and optimizing the mask masking process and the wafer making process, thereby minimizing variances between the final wafer pattern 80 and the target pattern. Computational lithography generally refers to any technique implementing computationally-intensive physical models and/or empirical models to predict and optimize IC feature patterning, where the physical models and/or the empirical models are based on phenomena that affect lithographic process results, such as imaging effects (for example, diffraction and/or interference) and/or resist chemistry. The IC manufacturing system 10 can implement such techniques to generate optimal settings for the illumination optics module 64 (often referred to as source optimization), the mask module 66 (often referred to as mask optimization), the projection optics module 68 (often referred to as wavefront engineering), and/or the target module 70 (often referred to as target optimization).

For example, the IC manufacturing system 10 can implement SMO to generate a shape for a final mask pattern of a mask (fabricated by the mask house 20) and a shape of radiation for exposing the mask (provided by the illumination optics module 64) that optimizes the projected wafer image 50. In another example, the IC manufacturing system 10 can implement wavefront engineering to generate settings for the projection optics module 68 that optimize the projected wafer image 50. In yet another example, the IC manufacturing system 10 can implement OPC, mask rule check (MRC), lithographic process check (LPC), and/or ILT techniques to generate a shape for a final mask pattern of a mask (fabricated by the mask house 20) that optimizes the projected wafer image 50.

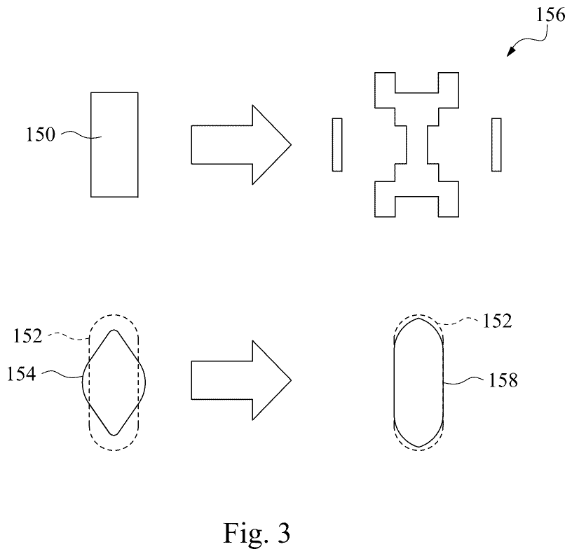

FIG. 3 is a schematic illustrating an OPC-based computational lithography process, which is performed at the mask data preparation 40 stage, according to various embodiments. For example, a target pattern includes a target feature 150 to be formed on a wafer. A target contour 152 defines a shape of a pattern printed (imaged) on the wafer by exposing a mask that includes the target feature 150 given ideal lithographic process conditions. Even with ideal lithographic process conditions, lithography constraints prevent the target feature 150 from being printed on the wafer with corners formed by right angles, such that the target contour 152 exhibits rounded corners. A predicted contour 154 represents a pattern printed on the wafer by exposing the mask that includes the target feature 150 given predicted lithographic process conditions.

In some implementations, the mask data preparation 40 can implement an LPC process to generate the predicted contour 154. The LPC process simulates an image of a mask based on a generated mask pattern using various LPC models (or rules), which are derived from actual (historic) processing data associated with the IC fab 25 fabricating IC devices. In some embodiments, the processing data includes processing conditions associated with various processes of the IC manufacturing cycle, conditions associated with tools used for manufacturing the IC, and/or other aspects of the manufacturing process. The LPC process considers various factors, such as image contrast, depth of focus, mask error sensitivity, other suitable factors, or combinations thereof.

As depicted in FIG. 3, since the predicted contour 154 varies from the target contour 152, OPC is performed to modify the target pattern until a predicted contour fits the target contour 152, thereby generating an OPC-modified target pattern. For example, a target feature 150 is transformed into an OPC-modified target feature 156 to compensate for lithographic process conditions that cause such variances, such that a predicted contour 158 is generated that fits the target contour 152, significantly improving lithography printability. The predicted contour 158 represents a pattern printed on the wafer by exposing a mask that includes the OPC-modified target feature 156 given predicted lithographic process conditions. In some implementations, an LPC process generates the predicted contour 158.

OPC uses lithography enhancement techniques to compensate for image distortions and errors, such as those that arise from diffraction, interference, or other process effects. OPC can add assist features (AFs), such as scattering bars, serifs, and/or hammerheads, to the target pattern (here, target feature 150) or modify (such as resize, reshape, and/or reposition) the target pattern according to optical models (referred to as model-based OPC) and/or optical rules (referred to as rule-based OPC), such that after a lithography process, a final wafer pattern exhibits enhanced resolution and precision. In some implementations, OPC distorts the target pattern to balance image intensity, for example, removing portions of the target pattern to reduce over-exposed regions and adding AFs to the target pattern to enhance under-exposed regions. In some implementations, AFs compensate for line width differences that arise from different densities of surrounding geometries. In some implementations, AFs can prevent line-end shortening and/or line-end rounding. OPC can further correct fore-beam proximity effects and/or perform other optimization features.

In some implementations, the OPC process and the LPC process are iterative processes, where multiple iterations (for example, modifications and simulations) are performed to generate an OPC-modified target feature 156. In some implementations, the target contour 152 is represented by a plurality of target points generated by an OPC process along a perimeter the defining target feature 150 (here, target contour 152), and the predicted contour 154 represents a perimeter defining the target feature 150 generated by an LPC process. In such implementations, a dissection process is performed on the target contour 152, where the target contour 152 is dissected into multiple discrete segments defined by a plurality of dissection points (also referred to as stitching points). Each segment is a portion of the target contour 152 defined between adjacent dissection points. Then, at least one target point is assigned to each segment, such that target points are spaced at locations along the target contour 152.

In some implementations, the OPC process modifies the target feature 150 until distances between target points of the target contour 152 and a predicted contour fall within an acceptable distance range. In some implementations, the mask data preparation 40 further implements an MRC process that checks the mask pattern after undergoing OPC, where the MRC process uses a set of mask creation rules. The mask creation rules can define geometric restrictions and/or connectivity restrictions to avoid various issues and/or failures that can arise from variations in IC manufacturing processes. FIG. 3 is simplified for the sake of clarity. Additional features can be added in the OPC-based computational lithography process, and some of the features described below can be replaced, modified, or eliminated for additional embodiments of the OPC-based computational lithography process.

OPC-based computational lithography techniques and computational lithography techniques aim to minimize a cost function that defines a variance between a predicted contour and a target contour, such as an edge placement error (EPE). The cost function can further correlate such variance with various penalties arising from process constraints related to the lithography process, such as an MRC penalty and/or an AF printing penalty. Though an optimized target pattern that exhibits a predicted contour with minimal variance from the target contour can be generated by such techniques, a shape of the target contour can negatively influence process windows. For example, obtaining a target contour with sharp corners under nominal conditions results in low contrast and/or low depth of focus. However, not every segment of a target contour has a distinct target. For example, a shape of the target contour can be varied (for example, to have rounded corners instead of sharp corners), yet still achieve a desired functionality of the target pattern.

As mentioned above, mask rule checking (MRC) is a process used to verify that the design of a photomask conforms to specific rules intended to ensure that the layout can be successfully transferred to the semiconductor wafer during the photolithography process. These rules are developed to address limitations inherent in the lithographic process, including resolution constraints, optical proximity effects, process variability, and the capabilities of the manufacturing equipment. Mask rule checking aims to ensure that the mask design is suitable for fabrication, minimizing potential defects and optimizing yield.

The development of mask rules typically involves input from design engineers, process engineers, and photomask manufacturers, and is based on several factors. These include the limitations of the photolithography process, such as the resolution of the lithography tools, and the physical effects that occur during pattern transfer to the wafer. Mask rules are also developed to account for potential variations in the manufacturing process, which can affect how features are transferred from the mask to the wafer. In addition, rules are established to address design considerations that impact manufacturability, such as feature size limitations and spacing requirements. The rules also account for the specifications of the lithography equipment, ensuring that the design is compatible with the capabilities of the equipment used in the manufacturing process.

Mask rules typically cover various aspects of the mask design, including minimum feature sizes, spacing between features, and corner and edge constraints. For example, the rules may specify the minimum distance between two features to avoid issues related to optical proximity effects, in which nearby features may interfere with each other during the printing process. Similarly, constraints may be placed on sharp angles and curved edges to prevent distortions that could arise during pattern transfer. Other rules may require certain features to be enclosed or expanded to ensure accurate replication during the photolithography process, compensating for potential shrinkage or distortions that may occur.

In practice, mask rule checking is integrated into the semiconductor design and manufacturing workflow. During the design phase, automated tools, such as Design Rule Checkers (DRCs) and mask rule-checking software, are used to verify that the layout complies with the established mask rules. If any violations are detected, the designer may modify the layout to bring it into compliance. Once the design passes the initial rule checks, it is typically subjected to a fracturing process, in which the layout is broken into smaller patterns that can be used to create the photomask. Mask rule checking continues during this phase to ensure that the fractured design remains manufacturable and free from issues that may arise during the photomask creation process.

After the mask is prepared, further mask rule checks are performed to confirm that the final mask design is suitable for the lithography process and that it will result in accurate pattern transfer to the wafer. This step helps identify any potential issues that could arise during the photolithography process, such as pattern distortions or defects in the mask itself. Mask rule checking is typically an iterative process, with adjustments made to the design as needed based on the results of each rule check. Only when the design passes all necessary rule checks is it deemed ready for the photomask manufacturing process.

Various software tools are employed to perform mask rule checking, including specialized mask rule-checking software and lithography simulation tools. These tools help designers and engineers identify potential issues with the mask design early in the process, enabling modifications to be made before the design is sent to the photomask manufacturer. Lithography simulation tools also assist in predicting how the mask design will behave during the photolithography process, ensuring that the patterns will be transferred accurately to the wafer.

According to certain embodiments, lithography masks include one or more curved features and are called curvilinear masks. Such curvilinear masks, which feature non-linear or curved patterns, require specific mask rule checks to ensure that their designs can be accurately transferred onto a wafer. As the use of curvilinear patterns becomes more common with shrinking design nodes, certain challenges arise due to the complexity and potential for distortion during the lithographic process. One fundamental mask rule check is the verification of the minimum feature size, ensuring that the smallest feature on the curvilinear mask is within the resolution limits of the lithography system. Curves with tight radii or intricate details may be difficult to resolve if they exceed the resolution capability of the photolithography tools. Similarly, minimum spacing checks are applied to verify that the distance between adjacent features, whether curved or linear, meets the required spacing to avoid optical proximity effects (OPE), which can cause pattern distortions or defects.

Curvilinear patterns often include curved corners or edges, which can be prone to distortion, so mask rule checks focus on ensuring that corner sharpness and edge smoothness meet specific criteria. Sharp transitions in curved patterns can lead to printing defects, so rules may enforce minimum radii of curvature or smoothness at corners to prevent issues with pattern transfer. Additionally, rules regarding enclosure and expansion are applied to ensure that certain features are sufficiently enclosed or expanded to facilitate accurate pattern transfer. Enclosure rules ensure that smaller features are fully enclosed within larger ones to prevent missing pattern transfer, while expansion rules may require certain features to be enlarged to account for potential resolution loss during the lithographic process.

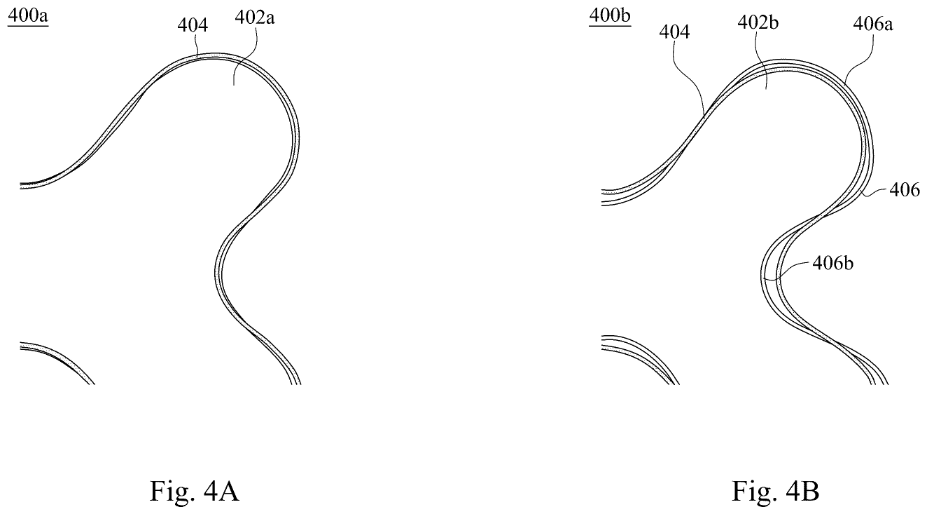

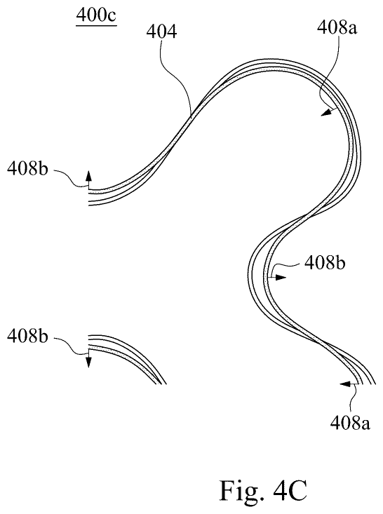

FIG. 4A illustrates a portion of an initial mask design 400a including curved features, and FIG. 4B illustrates a projected pattern 400b based on the initial mask design 400a that includes edge placement errors, according to various embodiments. As shown in FIG. 4A, the initial mask design 400a includes a mask feature having an area 402a that is bounded by a first curvilinear boundary 404. However, due to diffraction effects, a projected pattern 400b deviates from the initial mask design 402a. In this regard, the projected pattern 400b has an area 402b bounded by a second curvilinear boundary 406 that deviates from the curvilinear boundary 404 of the initial mask design 400a. As shown in FIG. 4B the second curvilinear boundary 406 includes a first portion 406a that is larger than the first curvilinear boundary 404 and a second portion 406b that is smaller than the first curvilinear boundary 404.

FIG. 4C illustrates a corrected mask design 400c, according to various embodiments. The corrected mask design 400c includes modifications to the curvilinear boundary 404 as shown by arrows (408a, 408b). As shown, the corrections include applying positive bias 408a in some places to locally reduce the size of the first curvilinear boundary 404 and applying negative bias 408b to locally increase the size of the first curvilinear boundary 404

The differences between the first curvilinear boundary 404 and the second curvilinear boundary 406 are understood in terms of diffraction effects and are quantified based on the theory of physical optics. Accordingly, the projected pattern 400b is given by a convolution of the original pattern with a Gaussian Point Spread Function (PSF) G(x, y) as follows:

$${M}_{proj} ( x , y ) = ( M * G ) ( x , y ) = {\int }_{- ∞}^{∞} {\int }_{- ∞}^{∞} M ( {x}^{′} , {y}^{′} ) G ( x - {x}^{′} , y - {y}^{′} ) {dx}^{′} {dy}^{′}$$

where M(x, y) represents the initial mask design 400a, Mₚᵣₒⱼ(x, y) represents the projected pattern 400b, and the Gaussian PSF G(x, y) is given by:

$$G ( x , y ) = \frac{1}{2 {πσ}^{2}} exp ( - \frac{{x}^{2} + {y}^{2}}{2 {σ}^{2}} )$$

where σ is a standard deviation that characterizes diffraction effects associated with a lithography system.

Deeper insight is gained by writing the initial mask design 400a as an inverse Fourier Transform:

$$M ( x , y ) = \int {\int }_{- ∞}^{∞} \hat{M} ( u , v ) exp ( i 2 π ( ux + vy ) ) du dv$$

where (u, v) are the spatial frequencies, and \hat{M}(u, v) is the Fourier Transform of the initial mask design 400a, which quantifies the amplitude of each Fourier component of the initial mask design 400a. By writing the initial mask design 400a as an inverse Fourier Transform, it becomes possible to quantify diffraction effects on individual Fourier components, as follows.

To simplify the analysis, a one-dimensional mask pattern M(x) having a single Fourier component is considered:

$$M ( x ) = A cos ( \frac{2 π x}{λ} )$$

where A is the amplitude and λ is a characteristic wavelength that is associated with the spatial variation of the one-dimensional mask pattern M(x). Diffraction effects associated with this one-dimensional mask pattern M(x) are quantified by performing a convolution with a one-dimensional Gaussian PSF:

$$G ( x ) = \frac{1}{\sqrt{2 {πσ}^{2}}} exp ( - \frac{{x}^{2}}{2 {σ}^{2}} )$$

$$\text{to give:}$$

$${M}_{proj} ( x ) = {\int }_{- ∞}^{∞} M ( {x}^{′} ) G ( x - {x}^{′} ) {dx}^{′} = A exp ( - \frac{2 {π}^{2} {σ}^{2}}{{λ}^{2}} ) cos ( \frac{2 π x}{λ} )$$

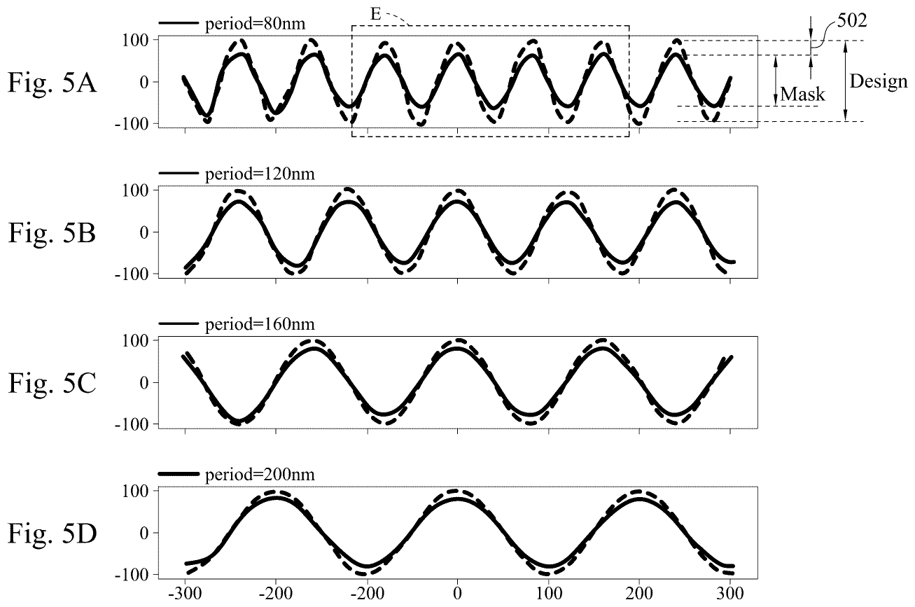

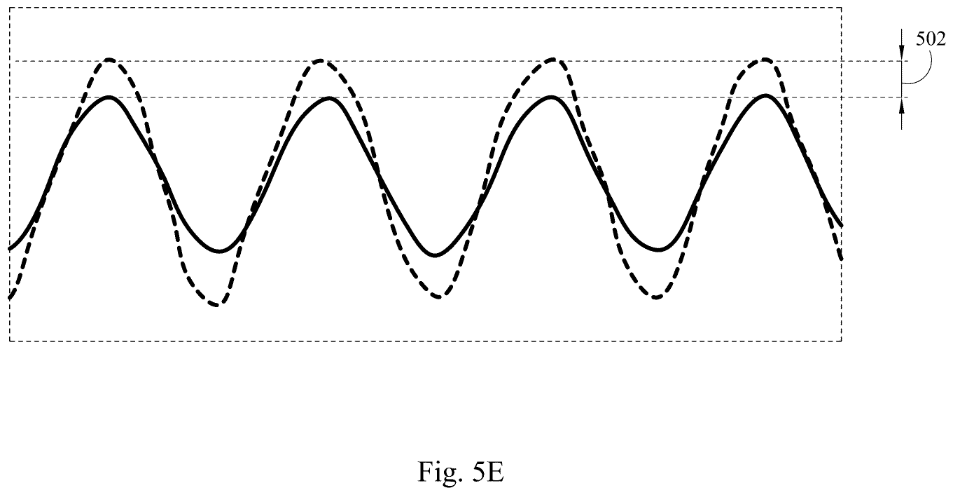

which shows that the wavelength λ is unaffected by the convolution, but the amplitude A is modified by the exponential factor. Further, the degree to which the amplitude is modified is wavelength-dependent with the greatest effects occurring for the shortest wavelengths and the least effects occurring for longer wavelengths, as shown in FIGS. 5A to 5E, below.

FIGS. 5A to 5D are plots illustrating diffraction effects for a single Fourier component respectively having 80 nm, 120 nm, 160 nm, and 200 nm wavelengths, according to various embodiments. These plots were generated by plotting the one-dimensional mask pattern M(x) and the projected mask pattern Mₚᵣₒⱼ (x) described by the above formulae for a fixed value of the standard deviation σ≈8 nm and for wavelengths λ=80 nm, 120 nm, 160 nm, and 200 nm. For these parameters, there is an amplitude deviation 502 such that the amplitude is reduced by a factor of 0.18, 0.08, 0.03, and 0.02, respectively in FIGS. 5A to 5D. The value chosen for the standard deviation σ≈8 nm is provided merely as an example and various other values of the standard deviation σ are provided in other embodiments. In general, the standard deviation σ can be determined by making optical measurements of diffraction effects associated with a lithographic system. Alternatively, the standard deviation σ is often provided by the manufacturer of the lithography tool and therefore can be determined by looking up the value of the standard deviation σ in a table or other resource provided by the manufacturer.

FIG. 5E is an enlarged portion E of FIG. 5A, illustrating the amplitude deviation 502 of the 80 nm Fourier component caused by diffraction effects, according to various embodiments. Disclosed embodiments provide geometric-based mask rule checkers based on the wavelength-dependent amplitude deviation 502 that is quantified by the above equations. In this regard, a useful rule for the amplitude deviation 502 is devised by considering the change in amplitude for long wavelengths. An expression for this deviation is derived by subtracting the projected mask pattern Mₚᵣₒⱼ(x) from the initial one-dimensional mask pattern M(x) and expanding the exponential to include the lowest order wavelength-dependent term as follows:

$$Δ M ( x ) = A cos ( \frac{2 π x}{λ} ) ( 1 - exp ( - \frac{2 {π}^{2} {σ}^{2}}{{λ}^{2}} ) ) \approx A cos ( \frac{2 π x}{λ} ) \frac{2 {π}^{2} {σ}^{2}}{{λ}^{2}}$$

thus, the fractional amplitude reduction is used to define a mask rule checker:

$$MRC 1 = const \times \frac{{σ}^{2}}{{λ}^{2}} .$$

according to an embodiment.

The above mask rule checker MRC1 can be used to estimate edge placement errors as follows. A curvilinear boundary of an initial mask design is segmented into a plurality of curved segments. For a sufficiently small segment, a given curved portion of the initial mask layout is approximated by a single cosine function which is fitted to data P(x) sampled from the curved portion. In some embodiments, a more general fitting function is written as:

$$M ( x ) = A cos ( \frac{2 π x}{λ} ) + B$$

which includes a characteristic offset B. The fitting procedure provides a characteristic amplitude A and a characteristic wavelength λ in addition to a characteristic offset B (which has a zero value in some embodiments). According to various embodiments, the fitting procedure is performed by defining a cost function

$$S ( M ) = {\sum }_{i = 1}^{N} {( M ( {x}_{i} ) - P ( {x}_{i} ) )}^{2}$$

where M(x) is the value of the model cosine function M(x) at the point xᵢ, P(xᵢ) is the corresponding data value at the point xᵢ, and N is the total number of data points. Various other cost functions can be provided in other embodiments.

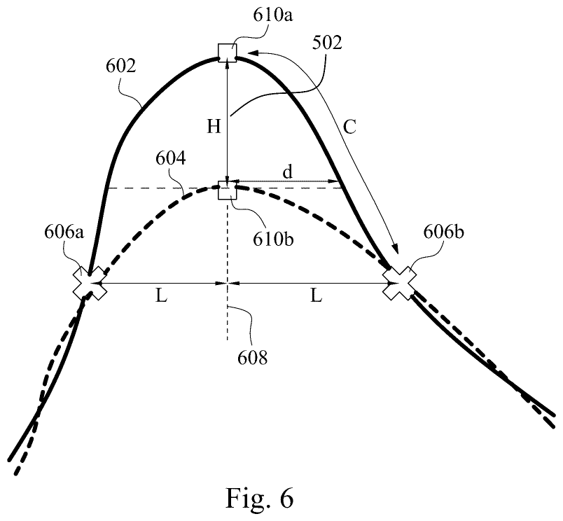

A standard deviation σ of a Gaussian PST characterizing diffraction effects associated with a target lithography system is then used in the above MRC1 formula to estimate edge placement errors arising from curved features in an initial mask design 400a. This embodiment mask rule checker provides a fast and efficient way to estimate edge placement errors and avoids the need for costly and time-consuming numerical simulations. Using the insights described above, other mask rule checkers are provided in other embodiments, as described with reference to FIG. 6, below.

FIG. 6 is a two-dimensional plot of a first curved portion 602 of a first curvilinear boundary 404 of an initial mask design 400a (e.g., see FIG. 4A) and a second curved portion 604 of a second curvilinear boundary 406 of a projected pattern 400b (e.g., see FIG. 4B), according to various embodiments. As described above, the first curved portion 602 and the second curved portion 604 deviate from one another due to diffraction effects. Further, as described above by mask rule checker MRC1, the deviation is greater for curved portions having higher wavelength Fourier components. As such, the deviation is smaller for portions of the initial mask design 400a that are smoother (i.e., have longer-wavelength Fourier components). As such, as shown in FIG. 6, the deviation is confined to a portion of the first curved portion 602 between two endpoints (606a, 606b). As such, the two endpoints (606a, 606b) are defined as points where the first curved portion 602, and the second curved portion 604 deviate by less than a threshold. Various thresholds are provided in respective embodiments depending on the application. For example, the threshold can be 1%, 0.1%, 0.01%, etc. These numerical values for the threshold are only provided as examples and other values of the threshold are provided in other embodiments.

A further mask rule checker can be defined in terms of the geometric construction shown in FIG. 6, as follows. The edge placement error between the first curved portion 602 and second curved portion 604 can be quantified by considering a distance H (shown as 502 in FIGS. 5A, 5E, and 6) between the first curved feature 602 and the second curved feature 604 measured along a symmetrically placed line 608 that intersects the first curved feature 602 at a first vertex 610a and intersects the second curved 604 feature at a second vertex 610b. According to certain embodiments, the distance H is called the absolute edge placement error. According to various embodiments, a model of the absolute edge placement error H is constructed by fitting a cosine function to the first curved portion 602 between the two endpoints (606a, 606b). Based on this model, a relation between an arc length 2C and a chord length 2L can be established. As described in greater detail below, the ratio R=C/L can be used in a further mask rule checker MRC2. In this regard, the absolute edge placement error H is shown to be given by a linear function of the ratio C/L, as follows.

The arc length between the first vertex 610a and the second endpoint 606b is given by the following expression:

$$C = {\int }_{0}^{L} \sqrt{1 + {{A}^{2} ( \frac{2 π}{λ} )}^{2} {sin}^{2} ( \frac{2 π x}{λ} )} dx$$

assuming that the first curved portion 602 is fit to a cosine function:

$$M ( x ) = A cos ( \frac{2 π x}{λ} )$$

as described above.

For long wavelengths, the above expression can be expanded to give the expression:

$$\frac{C}{L} \approx 1 + \frac{2 {A}^{2} {π}^{4} {L}^{2}}{3 {λ}^{4}}$$

and an expression for the absolute edge placement error His found by evaluating the above expression for M(x) at x=d (see FIG. 6) and subtracting the resulting expression from the amplitude A. The resulting expression is:

$$H = A \frac{2 {π}^{2} {d}^{2}}{{λ}^{2}} .$$

To the same degree of accuracy, the distance d can be approximated as d≈L, and combining with the above expression for C/L gives the following linear relation between the ratio C/L and the edge placement error H, which defines a further mask rule checker MRC2 as follows:

$$MRC 2 = H = A ( \frac{C}{L} - 1 ) \frac{{λ}^{2}}{2 {π}^{2} {L}^{2}} .$$

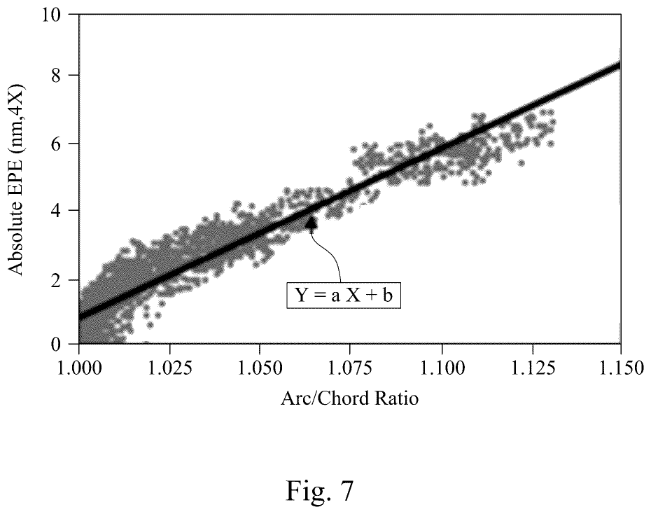

which is a linear relation of the form Y=ax+b, which is verified in FIG. 7, as follows.

FIG. 7 is a plot of the absolute edge placement error H vs. an arc/chord ratio C/L that verifies a linear relationship, according to various embodiments. The data points were generated by comparing a plurality of initial mask designs 400a to corresponding projected patterns 400b based on the initial mask design 400a to determine absolute edge placement errors H. A plurality of data sets were generated both using numerical simulations and experimental measurements.

First curved portions 602 and second curved portions 604 were identified and a fitting algorithm was performed to fit the first curved portion 602 with a cosine function M(x) as described above. The arc length C and chord length L were determined from the fitted cosine function based on a characteristic wavelength λ as determined from the fitted cosine function. The data sets include a plurality of pairs (Y, X) of data points, each comprising a first value X=C/L and a second value Y=H, with the second value H representing the measured absolute edge placement error and the first value C/L representing an estimated value of the ratio of the arc length 2C to the chord length 2L. A linear regression algorithm was then performed, based on assuming the linear relationship form Y=ax+b, which gives the solid black line through the data points confirming the relationship.

This embodiment mask rule checker MRC2 provides a fast and efficient way to estimate edge placement errors and avoids the need for costly and time-consuming numerical simulations. Depending on the application, one or both of the mask rule checkers (MRC1, MRC2) can be used to provide estimates of edge placement errors due to diffraction at curved surfaces.

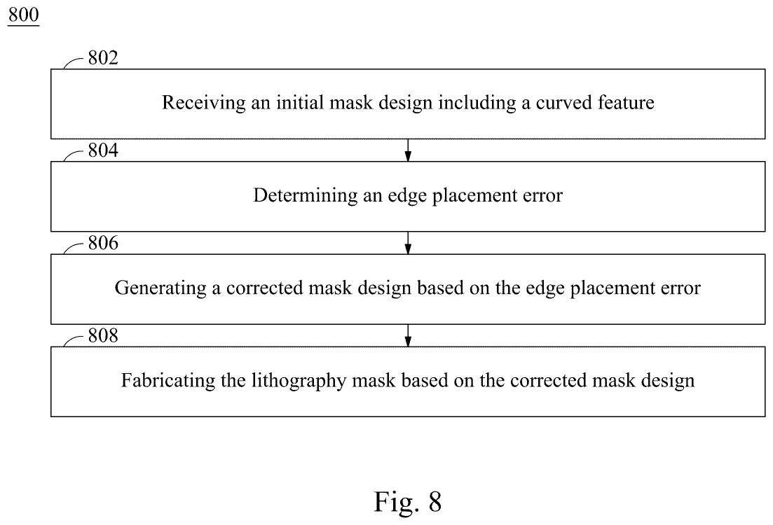

FIG. 8 is a flowchart illustrating operations of a method 800 of manufacturing a lithography mask, according to an embodiment. According to operation 802, the method 800 includes receiving an initial mask design 400a including a first curved feature 602. According to operation 804, the method 800 includes determining an edge placement error 502. According to operation 806, the method 800 includes generating a corrected mask design 400c based on the edge placement error 502. According to operation 808, the method 800 includes fabricating the lithography mask based on the corrected mask design 400c.

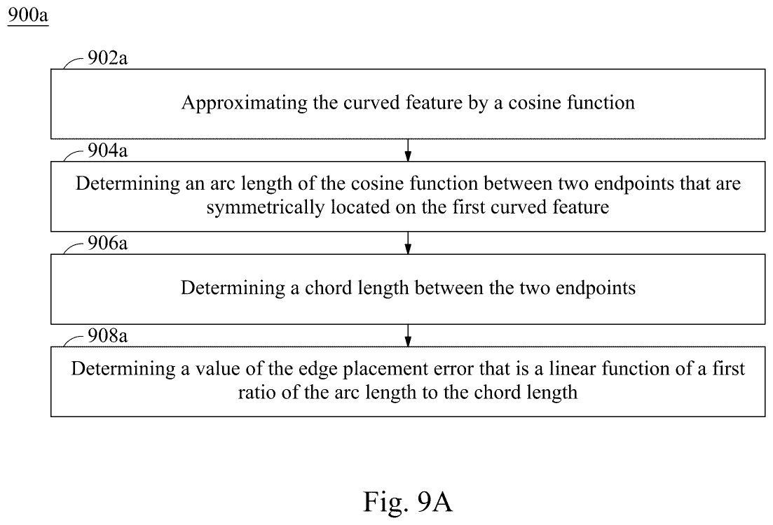

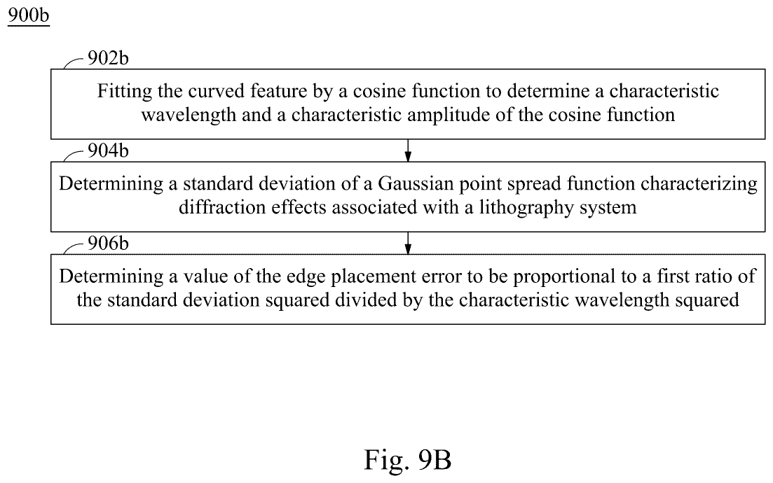

FIG. 9A is a flowchart illustrating operations of a method 900a of determining edge placement error 502 in operation 804 of the method 800 of FIG. 8. According to operation 902a, the method 900a includes approximating the first curved feature 602 by a cosine function M(x). According to operation 904a, the method 900a includes determining an arc length 2C of the cosine function M(x) between two endpoints (606a, 606b) that are symmetrically located on the first curved feature 602. According to operation 906a, the method 900a includes determining a chord length 2L between the two endpoints (606a, 606b). According to operation 908a, the method 900a includes determining a value of the edge placement error 502 which is a linear function of a first ratio C/L of the arc length 2C to the chord length 2L.

According to various embodiments, the method 900a further includes comparing the first curved feature 602 of the initial mask design 400a to a second curved feature 604 of a projected pattern and choosing the two endpoints (606a, 606b) to be located at positions where the first curved feature 602 and the second curved feature 604 deviate by less than a threshold (e.g., 1%, 0.1%, 0.01%, etc.). According to various embodiments, the method 900a further includes performing a numerical simulation to determine the projected pattern based on the initial mask design 400a, such that the projected pattern includes the second curved feature 604 that deviates from the first curved feature 602 due to the edge placement error 502.

According to various embodiments, the method 900a further includes fabricating a comparative lithography mask 400b based on the initial mask design 400a and measuring features of the comparative lithography mask 400b to determine the projected pattern that includes the second curved feature 604 that deviates from the first curved feature 602 due to the edge placement error 502. According to various embodiments, the method 900a further includes determining an absolute edge placement error 502 by measuring a distance H between the first curved feature 602 and the second curved feature 604 measured along a symmetrically placed line 608 that intersects the first curved feature 602 at a first vertex 610a and intersects the second curved feature 604 at a second vertex 610b, and determining a linear relationship Y=a X+b between the absolute edge placement error 502 and the first ratio C/L of the arc length 2C to the chord length 2L.

According to various embodiments, determining the linear relationship Y=a X+b further includes generating a data set including a plurality of pairs of data points (Y, X), each including a first value C/L and a second value H, with the first value Y representing the absolute edge placement error 502 and the second value X representing an estimated value of the first ratio C/L of the arc length 2C to the chord length 2L for a corresponding plurality of projected patterns (e.g., see FIG. 7); and performing a linear regression algorithm in which the two endpoints (606a, 606b) that define the arc length 2C and the chord length 2L are varied by the linear regression algorithm.

According to various embodiments, approximating the first curved feature 602 by the cosine function M(x) further includes performing a numerical fitting procedure in which a wavelength λ and an amplitude A of the cosine function M(x) are varied by the numerical fitting procedure to determine a characteristic wavelength λ and a characteristic amplitude A. According to various embodiments, the method 900a further includes performing the numerical fitting procedure using a linear offset variable B added to the cosine function M(x) to determine a characteristic offset B. According to various embodiments, the method 900a further includes determining a standard deviation σ of a Gaussian point spread function characterizing diffraction effects associated with a lithography system and determining the edge placement error 502 to be proportional to a second ratio σ²/λ² of the standard deviation squared σ² divided by the characteristic wavelength λ² squared.

FIG. 9B is a flowchart illustrating operations of a method 900b of determining edge placement error 502 in operation 804 of the method 800 of FIG. 8. According to operation 902b, the method 900b includes fitting the curved feature 602 by a cosine function M(x) to determine a characteristic wavelength λ and a characteristic amplitude A of the cosine function M(x). According to operation 904b, the method 900b includes determining a standard deviation σ of a Gaussian point spread function characterizing diffraction effects associated with a lithography system. According to operation 906b, the method 900b includes determining a value of the edge placement error 502 to be proportional to a first ratio σ²/λ² of the standard deviation squared σ² divided by the characteristic wavelength squared λ².

According to various embodiments, fitting the curved feature 602 further includes performing a numerical fitting algorithm, using data sampled from the curved feature 602 between two endpoints (606a, 606b) that are symmetrically located on the curved feature 602, and varying a wavelength and an amplitude of the cosine function M(x) to determine the characteristic wavelength and the characteristic amplitude of the cosine function M(x) by minimizing a cost function that characterized deviations between the curved feature 602 and the cosine function M(x). According to various embodiments, the method 900b further includes performing the numerical fitting algorithm using a linear offset variable B added to the cosine function M(x) to determine a characteristic offset B.

According to various embodiments, generating the corrected mask design 400c further includes adding a positive bias 408a or negative 408b bias to the curved feature 602 to respectively reduce or enlarge a size of the curved feature 602 to thereby reduce the edge placement error 502. According to various embodiments, generating the corrected mask design 400c further includes modifying the initial mask design 400a by adding at least one of serifs or optical proximity assist features 156.

According to various embodiments, the method 900b further includes determining an arc length 2C of the cosine function M(x) between the two endpoints (606a, 606b), determining a chord length 2L between the two endpoints (606a, 606b), defining a mask checker rule MRC2 to be a linear function of a second ratio of the arc length 2C divided by the chord length 2L, and generating the corrected mask design 400c using the mask checker rule MRC2 to determine a magnitude of a positive bias 408a or negative 408b bias that is introduced to the curved feature 602 to respectively reduce or enlarge a size of the curved feature 602 to thereby reduce the edge placement error 502.

According to various embodiments, the above-described methods (800, 900a, 900b) are embodied in computer program instructions stored on a non-transitory computer-readable storage medium. For example, some embodiments include a non-transitory computer-readable storage medium having computer program instructions stored thereon that, when executed by a processor of a controller device, cause the controller device to perform method (800, 900a, 900b) operations, according to various embodiments. For example, according to an embodiment, the operations include receiving an initial mask design 400a including a first curved feature 602; determining an edge placement error 502; generating a corrected mask design 400c based on the edge placement error 502; and controlling a mask fabrication device to fabricate a lithographic mask based on the corrected mask design 400c.

As described with reference to FIG. 9A, the method 900a operations further include approximating the first curved feature 602 by a cosine function M(x); determining an arc length 2C of the cosine function M(x) between two endpoints (606a, 606b) that are symmetrically located on the first curved feature 602; determining a chord length 2L between the two endpoints (606a, 606b); and determining a value of the edge placement error 502 that is a linear function of a ratio of the arc length 2C to the chord length 2L.

According to various embodiments, the method (800, 900a, 900b) operations further include comparing the first curved feature 602 of the initial mask design 400a to a second curved feature 604 of a projected pattern; and choosing the two endpoints (606a, 606b) to be located at positions where the first curved feature 602 and the second curved feature 604 deviate by less than a threshold. According to various embodiments, the method (800, 900a, 900b) operations further include performing a numerical simulation to determine the projected pattern based on the initial mask design 400a, wherein the projected pattern includes the second curved feature 604 that deviates from the first curved feature 602 due to the edge placement error 502.

According to various embodiments, the method (800, 900a, 900b) operations further include performing a numerical fitting procedure using a linear offset variable added to the cosine function M(x) such that a wavelength, an amplitude, and the linear offset variable are varied to determine a characteristic wavelength, a characteristic amplitude, and a characteristic offset. According to various embodiments, the method (800, 900a, 900b) operations further include determining a standard deviation of a Gaussian point spread function characterizing diffraction effects associated with a lithography system; and determining the edge placement error 502 to be proportional to a ratio of the standard deviation squared divided by the characteristic wavelength squared.

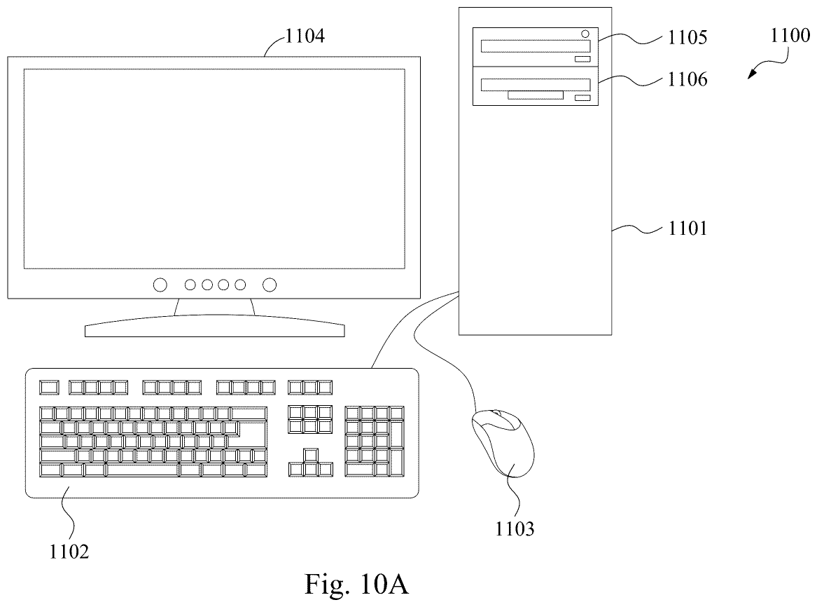

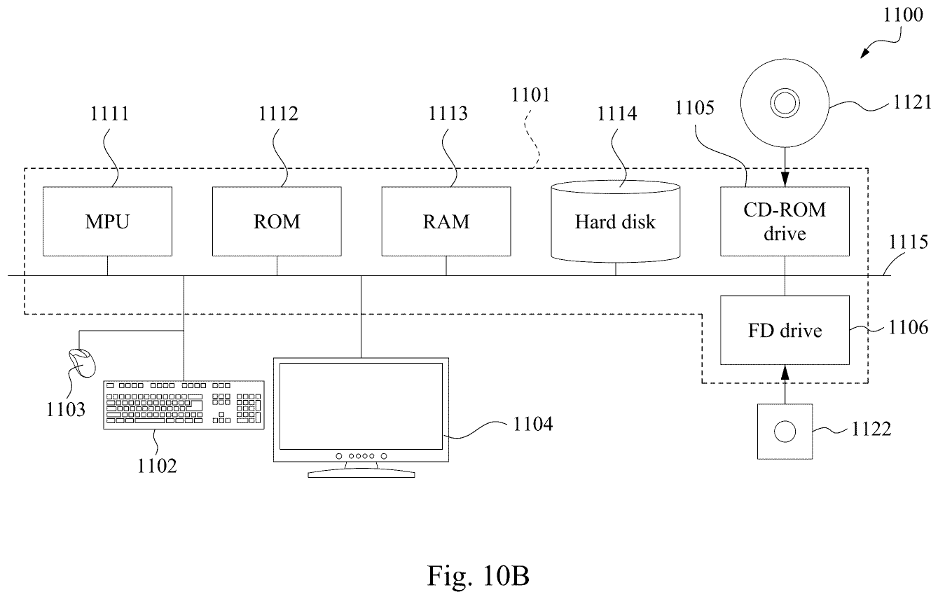

FIGS. 10A and 10B illustrate an apparatus 1100 configured to perform the methods of FIGS. 8, 9A, and 9B, according to various embodiments. In some embodiments, the apparatus 1100 is an optical simulator and/or a mask data preparation apparatus 1100. FIG. 10A is a schematic view of a computer system that executes the processes of defining a mask layout according to one or more embodiments as described above. All of or a part of the processes, methods, and/or operations of the above-described embodiments can be realized using computer hardware and computer programs executed thereon. As shown in FIG. 10A, a computer system 1100 is provided with a computer 1101 including an optical disk read-only memory (e.g., CD-ROM or DVD-ROM) drive 1105 and a magnetic disk drive 1106, a keyboard 1102, a mouse 1103, and a monitor 1104.

FIG. 10B is a diagram showing an internal configuration of the computer system 1100. The computer 1101 is provided with, in addition to the optical disk drive 1105 and the magnetic disk drive 1106, one or more processors 1111, such as a micro processing unit (MPU), a read-only memory (ROM) 1112 in which a program, such as a boot-up program is stored, a random access memory (RAM) 1113 that is connected to the MPU 1111 and in which a command of an application program is temporarily stored and a temporary storage area is provided, a hard disk 1114 in which an application program, a system program, and data are stored, and a bus 1115 that connects the MPU 1111, the ROM 1112, and the like. Note that the computer 1101 may include a network card (not shown) for providing a connection to a LAN.

Computer program instructions, configured to cause the computer system 1100 to execute the process for defining a mask layout in the foregoing embodiments are stored in a non-transitory computer-readable storage medium, such as an optical disk 1121 or a magnetic disk 1122. Such a storage medium is configured to be inserted into the optical disk drive 1105 or the magnetic disk drive 1106, and transmitted to the hard disk 1114. Alternatively, the program may be transmitted via a network (not shown) to the computer 1101 and stored in the hard disk 1114 (or other non-transitory computer-readable storage medium). At the time of execution, the program is loaded into the RAM 1113. The program may be loaded from the optical disk 1121 or the magnetic disk 1122, or directly from a network. The program does not necessarily need to include, for example, an operating system (OS) or a third-party program to cause the computer 1101 to execute the process for manufacturing the lithographic mask of a semiconductor device in the foregoing embodiments. The program may only include a command portion to call an appropriate function (module) in a controlled mode and obtain desired results.

Disclosed embodiments are advantageous by providing mask rule checkers (MRC1, MRC2) that allow fast and efficient estimates of edge placement errors 502 in mask design (400a, 400b, 400c), avoiding the need for costly and time-consuming numerical simulations. Disclosed embodiments are based on fundamental principles of physical optics combined with geometric considerations of curved mask features (602, 604) and have been validated by both experiments and simulations (e.g., see FIG. 7). According to various embodiments, determining the edge placement error 502 includes approximating a curved feature 602 by a cosine function M(x), determining an arc length 2C of the cosine function M(x) between two endpoints (602a, 602b) that are symmetrically located on the curved feature 602, determining a chord length 2L between the two endpoints (602a, 602b), and determining a value of the edge placement error 502 to be a linear function Y=a X+b of a first ratio X=C/L of the arc length 2C to the chord length 2L (e.g., see FIGS. 6 and 7 with Y=H (502)). In other embodiments, the edge placement error 502 is a value that is proportional to a second ratio σ²/λ² of a squared standard deviation σ² (characterizing diffraction effects) divided by a squared characteristic wavelength λ² of the cosine function.

According to various embodiments, a method of manufacturing a lithography mask is provided. The method includes receiving an initial mask design including a first curved feature, determining an edge placement error, generating a corrected mask design based on the edge placement error, and fabricating the lithography mask based on the corrected mask design. According to various embodiments, determining the edge placement error includes approximating the first curved feature by a cosine function, determining an arc length of the cosine function between two endpoints that are symmetrically located on the first curved feature, determining a chord length between the two endpoints, and determining a value of the edge placement error that is a linear function of a first ratio of the arc length to the chord length.

According to various embodiments, the method further includes comparing the first curved feature of the initial mask design to a second curved feature of a projected pattern and choosing the two endpoints to be located at positions where the first curved feature and the second curved feature deviate by less than a threshold. According to various embodiments, the method further includes performing a numerical simulation to determine the projected pattern based on the initial mask design, such that the projected pattern includes the second curved feature that deviates from the first curved feature due to the edge placement error. According to various embodiments, the method further includes fabricating a comparative lithography mask based on the initial mask design and measuring features of the comparative lithography mask to determine the projected pattern that includes the second curved feature that deviates from the first curved feature due to the edge placement error.

According to various embodiments, the method further includes determining an absolute edge placement error by measuring a distance between the first curved feature and the second curved feature measured along a symmetrically placed line that intersects the first curved feature at a first vertex and intersects the second curved feature at a second vertex, and determining a linear relationship between the absolute edge placement error and the first ratio of the arc length to the chord length.

According to various embodiments, determining the linear relationship further includes generating a data set including a plurality of pairs of data points, each including a first value and a second value, with the first value representing the absolute edge placement error and the second value representing an estimated value of the first ratio of the arc length to the chord length for a corresponding plurality of projected patterns, and performing a linear regression algorithm in which the two endpoints that define the arc length and the chord length are varied by the linear regression algorithm. According to various embodiments, approximating the first curved feature by the cosine function further includes performing a numerical fitting procedure in which a wavelength and an amplitude of the cosine function are varied by the numerical fitting procedure to determine a characteristic wavelength and a characteristic amplitude.

According to various embodiments, the method further includes performing the numerical fitting procedure using a linear offset variable added to the cosine function to determine a characteristic offset. According to various embodiments, the method further includes determining a standard deviation of a Gaussian point spread function characterizing diffraction effects associated with a lithography system and determining the edge placement error to be proportional to a second ratio of the standard deviation squared divided by the characteristic wavelength squared.

According to various embodiments, a method of manufacturing a lithography mask is provided. The method includes receiving an initial mask design including a curved feature, determining an edge placement error, generating a corrected mask design based on the edge placement error, and fabricating the lithography mask based on the corrected mask design, According to various embodiments, determining the edge placement error includes fitting the curved feature by a cosine function to determine a characteristic wavelength and a characteristic amplitude of the cosine function, determining a standard deviation of a Gaussian point spread function characterizing diffraction effects associated with a lithography system, and determining a value of the edge placement error to be proportional to a first ratio of the standard deviation squared divided by the characteristic wavelength squared.

According to various embodiments, fitting the curved feature further includes performing a numerical fitting algorithm, using data sampled from the curved feature between two endpoints that are symmetrically located on the curved feature, and varying a wavelength and an amplitude of the cosine function to determine the characteristic wavelength and the characteristic amplitude of the cosine function by minimizing a cost function that characterized deviations between the curved feature and the cosine function. According to various embodiments, the method further includes performing the numerical fitting algorithm using a linear offset variable added to the cosine function to determine a characteristic offset. According to various embodiments, generating the corrected mask design further includes adding a positive or negative bias to the curved feature to respectively reduce or enlarge a size of the curved feature to thereby reduce the edge placement error. According to various embodiments, generating the corrected mask design further includes modifying the initial mask design by adding at least one of serifs or optical proximity assist features.

According to various embodiments, the method further includes determining an arc length of the cosine function between the two endpoints, determining a chord length between the two endpoints, defining a mask checker rule to be a linear function of a second ratio of the arc length divided by the chord length, and generating the corrected mask design using the mask checker rule to determine a magnitude of a positive or negative bias that is introduced to the curved feature to respectively reduce or enlarge a size of the curved feature to thereby reduce the edge placement error.

According to various embodiments, the method operations are encoded in computer program instructions stored on a non-transitory computer-readable storage medium that, when executed by a processor of a controller device, cause the controller device to perform the method operations. According to various embodiments, the method operations include receiving an initial mask design including a first curved feature, determining an edge placement error, generating a corrected mask design based on the edge placement error, and controlling a mask fabrication device to fabricate a lithographic mask based on the corrected mask design. According to various embodiments, determining the edge placement error includes approximating the first curved feature by a cosine function, determining an arc length of the cosine function between two endpoints that are symmetrically located on the first curved feature, determining a chord length between the two endpoints, and determining a value of the edge placement error that is a linear function of a ratio of the arc length to the chord length.

According to various embodiments, the non-transitory computer-readable storage medium includes additional computer program instructions that, when executed by the processor of the controller device, cause the controller device to perform additional operations including comparing the first curved feature of the initial mask design to a second curved feature of a projected pattern, and choosing the two endpoints to be located at positions where the first curved feature and the second curved feature deviate by less than a threshold. According to various embodiments, the non-transitory computer-readable storage medium includes additional computer program instructions that, when executed by the processor of the controller device, cause the controller device to perform additional operations including performing a numerical simulation to determine the projected pattern based on the initial mask design, such that the projected pattern includes the second curved feature that deviates from the first curved feature due to the edge placement error.

According to various embodiments, the non-transitory computer-readable storage medium includes additional computer program instructions that, when executed by the processor of the controller device, cause the controller device to perform additional operations including performing a numerical fitting procedure using a linear offset variable added to the cosine function such that a wavelength, an amplitude, and the linear offset variable are varied to determine a characteristic wavelength, a characteristic amplitude, and a characteristic offset. According to various embodiments, the non-transitory computer-readable storage medium includes additional computer program instructions that, when executed by the processor of the controller device, cause the controller device to perform additional operations including determining a standard deviation of a Gaussian point spread function characterizing diffraction effects associated with a lithography system, and determining the edge placement error to be proportional to a ratio of the standard deviation squared divided by the characteristic wavelength squared.

The foregoing outlines features of several embodiments or examples so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments or examples introduced herein. Those skilled in the art should also realize that such equivalent constructions do not depart from the spirit and scope of the present disclosure and that they may make various changes, substitutions, and alterations herein without departing from the spirit and scope of the present disclosure.

What is claimed is:

1. A method of manufacturing a lithography mask, comprising:
receiving an initial mask design comprising a first curved feature;
determining an edge placement error;
generating a corrected mask design based on the edge placement error; and
fabricating the lithography mask based on the corrected mask design, wherein determining the edge placement error comprises:
approximating the first curved feature by a cosine function;
determining an arc length of the cosine function between two endpoints that are symmetrically located on the first curved feature;
determining a chord length between the two endpoints; and
determining a value of the edge placement error that is a linear function of a first ratio of the arc length to the chord length.

2. The method of claim 1, further comprising:
comparing the first curved feature of the initial mask design to a second curved feature of a projected pattern; and
choosing the two endpoints to be located at positions where the first curved feature and the second curved feature deviate by less than a threshold.

3. The method of claim 2, further comprising:
performing a numerical simulation to determine the projected pattern based on the initial mask design,
wherein the projected pattern includes the second curved feature that deviates from the first curved feature due to the edge placement error.

4. The method of claim 2, further comprising:
fabricating a comparative lithography mask based on the initial mask design; and
measuring features of the comparative lithography mask to determine the projected pattern that includes the second curved feature that deviates from the first curved feature due to the edge placement error.

5. The method of claim 2, further comprising:
determining an absolute edge placement error by measuring a distance between the first curved feature and the second curved feature measured along a symmetrically placed line that intersects the first curved feature at a first vertex and intersects the second curved feature at a second vertex; and
determining a linear relationship between the absolute edge placement error and the first ratio of the arc length to the chord length.

6. The method of claim 5, wherein determining the linear relationship further comprises:
generating a data set comprising a plurality of pairs of data points, each comprising a first value and a second value, with the first value representing the absolute edge placement error and the second value representing an estimated value of the first ratio of the arc length to the chord length for a corresponding plurality of projected patterns; and
performing a linear regression algorithm in which the two endpoints that define the arc length and the chord length are varied by the linear regression algorithm.

7. The method of claim 1, wherein approximating the first curved feature by the cosine function further comprises:
performing a numerical fitting procedure in which a wavelength and an amplitude of the cosine function are varied by the numerical fitting procedure to determine a characteristic wavelength and a characteristic amplitude.

8. The method of claim 7, further comprising:
performing the numerical fitting procedure using a linear offset variable added to the cosine function to determine a characteristic offset.

9. The method of claim 8, further comprising:
determining a standard deviation of a Gaussian point spread function characterizing diffraction effects associated with a lithography system; and
determining the edge placement error to be proportional to a second ratio of the standard deviation squared divided by the characteristic wavelength squared.

10. A method of manufacturing a lithography mask, comprising:
receiving an initial mask design comprising a curved feature;
determining an edge placement error;
generating a corrected mask design based on the edge placement error; and
fabricating the lithography mask based on the corrected mask design,
wherein determining the edge placement error comprises:
fitting the curved feature by a cosine function to determine a characteristic wavelength and a characteristic amplitude of the cosine function;
determining a standard deviation of a Gaussian point spread function characterizing diffraction effects associated with a lithography system; and
determining a value of the edge placement error to be proportional to a first ratio of the standard deviation squared divided by the characteristic wavelength squared.

11. The method of claim 10, wherein fitting the curved feature further comprises:
performing a numerical fitting algorithm, using data sampled from the curved feature between two endpoints that are symmetrically located on the curved feature; and
varying a wavelength and an amplitude of the cosine function to determine the characteristic wavelength and the characteristic amplitude of the cosine function by minimizing a cost function that characterized deviations between the curved feature and the cosine function.

12. The method of claim 11, further comprising:
performing the numerical fitting algorithm using a linear offset variable added to the cosine function to determine a characteristic offset.

13. The method of claim 10, wherein generating the corrected mask design further comprises:
adding a positive or negative bias to the curved feature to respectively reduce or enlarge a size of the curved feature to thereby reduce the edge placement error.

14. The method of claim 10, wherein generating the corrected mask design further comprises modifying the initial mask design by adding at least one of serifs or optical proximity assist features.

15. The method of claim 11, further comprising:
determining an arc length of the cosine function between the two endpoints;
determining a chord length between the two endpoints;
defining a mask checker rule to be a linear function of a second ratio of the arc length divided by the chord length; and
generating the corrected mask design using the mask checker rule to determine a magnitude of a positive or negative bias that is introduced to the curved feature to respectively reduce or enlarge a size of the curved feature to thereby reduce the edge placement error.

16. A non-transitory computer-readable storage medium having computer program instructions stored thereon that, when executed by a processor of a controller device, cause the controller device to perform operations comprising:
receiving an initial mask design comprising a first curved feature;
determining an edge placement error;
generating a corrected mask design based on the edge placement error; and
controlling a mask fabrication device to fabricate a lithographic mask based on the corrected mask design,
wherein determining the edge placement error comprises:
approximating the first curved feature by a cosine function;
determining an arc length of the cosine function between two endpoints that are symmetrically located on the first curved feature;
determining a chord length between the two endpoints; and
determining a value of the edge placement error that is a linear function of a ratio of the arc length to the chord length.

17. The non-transitory computer-readable storage medium of claim 16, further comprising additional computer program instructions that, when executed by the processor of the controller device, cause the controller device to perform additional operations comprising:
comparing the first curved feature of the initial mask design to a second curved feature of a projected pattern; and
choosing the two endpoints to be located at positions where the first curved feature and the second curved feature deviate by less than a threshold.

18. The non-transitory computer-readable storage medium of claim 17, further comprising additional computer program instructions that, when executed by the processor of the controller device, cause the controller device to perform additional operations comprising:
performing a numerical simulation to determine the projected pattern based on the initial mask design,
wherein the projected pattern includes the second curved feature that deviates from the first curved feature due to the edge placement error.

19. The non-transitory computer-readable storage medium of claim 16, further comprising additional computer program instructions that, when executed by the processor of the controller device, cause the controller device to perform additional operations comprising:
performing a numerical fitting procedure using a linear offset variable added to the cosine function such that a wavelength, an amplitude, and the linear offset variable are varied to determine a characteristic wavelength, a characteristic amplitude, and a characteristic offset.

20. The non-transitory computer-readable storage medium of claim 19, further comprising additional computer program instructions that, when executed by the processor of the controller device, cause the controller device to perform additional operations comprising:
determining a standard deviation of a Gaussian point spread function characterizing diffraction effects associated with a lithography system; and
determining the edge placement error to be proportional to a ratio of the standard deviation squared divided by the characteristic wavelength squared.
